(19) United States
(12) Patent Application Publication
(10) Pub. No.: US 2024/0128295 A1
(43) Pub. Date: Apr. 18, 2024

(54) OPTICAL SENSOR AND METHOD FOR FABRICATING AN OPTICAL SENSOR

(71) Applicant: Infineon Technologies AG, Neubiberg (DE)

(72) Inventors: Dirk VIETZKE, Vaterstetten (DE); Tobias MONO, Dresden (DE)

(21) Appl. No.: 18/480,704

(22) Filed: Oct. 4, 2023

(30) Foreign Application Priority Data
Oct. 18, 2022 (EP) 222024FE0288

(51) Int. Cl. H01L 27/146; G01S 7/481

(52) U.S. Cl. CPC H01L 27/1463; G01S 7/4816; H01L 27/14649; H01L 27/14689

(57) ABSTRACT

An optical sensor includes a pixel including a photoactive region configured to convert photons into charge carriers, a first and a second modulation gate configured to be modulated for indirect time of flight measurement, a first and a second storage node arranged on opposite sides of the photoactive region, the first and second storage nodes being configured to pin electrons generated in the photoactive region when the first or the second modulation gate is active, respectively, and a first field plate arranged next to the first storage node and a second field plate arranged next to the second storage node. The first and second field plates are configured to be supplied with a negative bias voltage such that the first and second field plates provide electrical isolation for the first or the second storage node, respectively.

### CROSS-REFERENCE TO RELATED APPLICATION

This application claims priority to European Patent Application No. 22202288 filed on Oct. 18, 2022, the content of which is incorporated by reference herein in its entirety.

### TECHNICAL FIELD

This disclosure relates in general to an optical sensor, in particular an optical sensor, wherein a pixel comprises field plates, as well as to a method for fabricating such an optical sensor.

### BACKGROUND

Optical sensors, in particular indirect time of flight (iToF) sensors, may use pixels with gate modulated storage nodes or memory nodes. A shallow trench isolation (STI) structure may be used to provide the required electrical isolation for these storage nodes. However, such optical sensors may exhibit a comparatively strong dark current due to the fact that a large part to the dark current is caused by electron-hole recombination at the STI interface. In order to improve such optical sensors, it may be desirable to provide a pixel with an electrical isolation structure which has a reduced impact on the dark current. Furthermore, it may also be desirable for such an electrical isolation structure to show a reduced impact on full well capacitance of the storage nodes compared to e.g., a junction isolation structure. Improved optical sensors as well as improved methods for fabricating optical sensors may help with solving these and other problems.

The problem on which the implementation is based is solved by the features of the independent claims. Further advantageous examples are described in the dependent claims.

### SUMMARY

Various aspects pertain to an optical sensor comprising at least one pixel, the pixel comprising: a photoactive region configured to convert photons into charge carriers, a first and a second modulation gate configured to be modulated for indirect time of flight measurement, a first and a second storage node arranged on opposite sides of the photoactive region, the first and second storage nodes being configured to pin electrons generated in the photoactive region when the first, respectively the second modulation gate is active, and a first field plate arranged next to the first storage node at a first lateral side of the pixel and a second field plate arranged next to the second storage node at an opposite second lateral side of the pixel, wherein the first and second field plates are configured to be supplied with a negative bias voltage such that the first and second field plates provide electrical isolation for the first, respectively the second storage node.

Various aspects pertain to a method for fabricating at least one pixel for an optical sensor, the method comprising: fabricating a photoactive region configured to convert photons into charge carriers, fabricating a first and a second modulation gate configured to be modulated for indirect time of flight measurement, fabricating a first and a second storage node on opposite sides of the photoactive region, the first and second storage nodes being configured to pin electrons generated in the photoactive region when the first, respectively the second modulation gate is active, and fabricating a first field plate next to the first storage node at a first lateral side of the pixel and fabricating a second field plate next to the second storage node at an opposite second lateral side of the pixel, wherein the first and second field plates are configured to be supplied with a negative bias voltage such that the first and second field plates provide electrical isolation for the first, respectively the second storage node.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIG. 1 shows a plan view of a pixel for an optical sensor, wherein the pixel comprises field plates configured to be supplied with a bias voltage such that the field plates provide electrical isolation for storage nodes of the pixel.

FIG. 2 shows an optical sensor comprising a sensor part and a control part configured to control the sensor part.

FIGS. 3A and 3B show sectional views of example pixels for an optical sensor, wherein in the example of FIG. 3A the pixel comprises field plates in the form of oxide structures and in the example of FIG. 3B the pixel comprises field plates in the form of trenches.

FIG. 4 shows a plan view of a further pixel for an optical sensor.

FIG. 5 shows an optical sensor unit configured to measure a distance between the sensor unit and an object and/or to measure a velocity of that object.

FIG. 6 is a flow chart of an example method for fabricating an optical sensor.

### DETAILED DESCRIPTION

In the following detailed description, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted.

The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “coupled”, or “connected” elements. However, it is also possible that the “bonded”, “coupled”, or “connected” elements are in direct contact with each other. Also, the term “example” is merely meant as an example, rather than the best or optimal.

In several examples layers or layer stacks are applied to one another or materials are applied or deposited onto layers. It should be appreciated that any such terms as “applied” or “deposited” are meant to cover literally all kinds and techniques of applying layers onto each other. In particular, they are meant to cover techniques in which layers are applied at once as a whole as well as techniques in which layers are deposited in a sequential manner.

An efficient optical sensor and an efficient method for fabricating an optical sensor may for example reduce material consumption, ohmic losses, chemical waste, etc. and thus enable energy and/or resource savings. Improved optical sensors and improved methods for fabricating an optical sensor, as specified in this description, may thus at least indirectly contribute to green technology solutions, e.g., climate-friendly solutions providing a mitigation of energy and/or resource use.

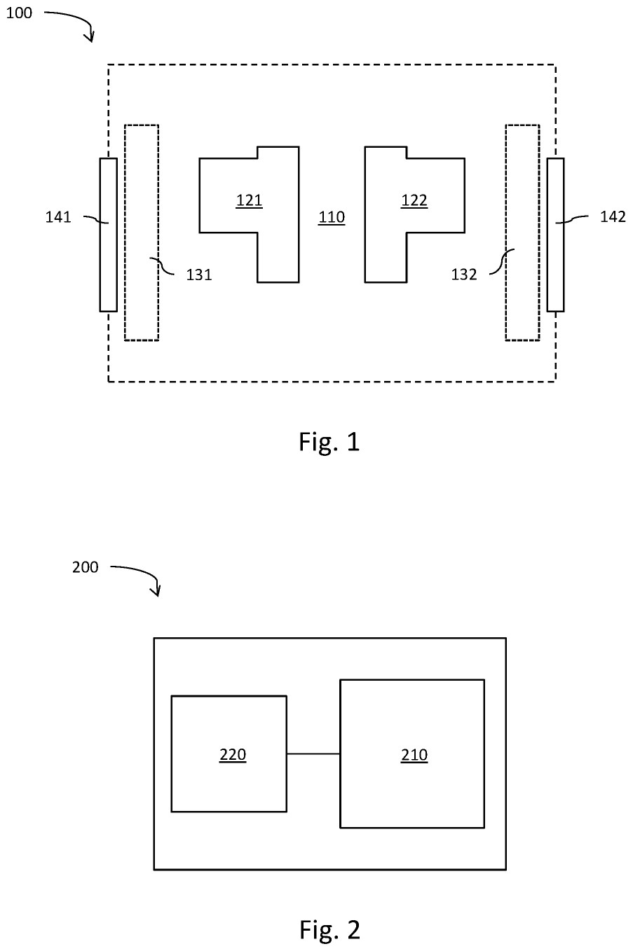

FIG. 1 shows a plan view of a pixel 100 comprising a photoactive region 110, a first modulation gate 121, a second modulation gate 122, a first storage node 131, a second storage node 132, a first field plate 141 and a second field plate 142.

The pixel 100 may be part of an optical sensor, wherein the optical sensor may comprise a single pixel 100 or a plurality of pixels 100. The plurality of pixels may e.g., be arranged in an array. The array of pixels 100 may be part of a common substrate (this is indicated by the dashed outline of the pixel 100 in FIG. 1). The optical sensor may for example be an active-pixel sensor (APS). The optical sensor may for example be (part of) a time of flight (ToF) sensor device, in particular an indirect ToF sensor device.

The pixel 100 may comprise any suitable semiconductor material, e.g., Si and/or Ge. The pixel 100 may for example be configured to be sensitive in the infrared (IR) and/or the near-IR spectrum, e.g., for incident light at a wavelength of about 850 nm and/or about 940 nm. According to an example, the pixel 100 is configured for backside illumination. According to another example, the pixel 100 is configured for front side illumination (wherein the front side is the side shown in FIG. 1).

The photoactive region 110 is configured to convert incident photons into charge carriers, in particular into electrons and holes. The photoactive region 100 may in particular be configured to convert the incident photons into electrons and holes via the inner photoelectric effect. The photoactive region 110 may be fabricated in one or more epitaxial layers. The photoactive region 110 may for example comprise one or more n-type epitaxial layers, e.g., n-type epitaxial Si layers.

The first and second modulation gates 121, 122 are configured to be modulated for indirect time of flight measurements. The first and second modulation gates 121, 122 may essentially be arranged above the photoactive region 110. The modulation gates 121, 122 may in particular be arranged at the front side of the pixel 100. The first and second modulation gates 121, 122 may for example comprise or consist of a poly-Si structure.

The first storage node 131 and the second storage node 132 are arranged at opposite sides of the photoactive region 110 (in particular, the storage nodes 131, 132 may be arranged close to opposite lateral edges of the pixel 100). The first storage node 131 is configured to pin (or to bin) electrons generated in the photoactive region 110 when the first modulation gate 121 is active and the second storage node 132 is configured to pin (or to bin) electrons generated in the photoactive region 110 when the second modulation gate 122 is active.

The first and second storage nodes 131, 132 may be arranged below the front side of the pixel 100 (this is indicated in FIG. 1 by the dashed outlines of the storage nodes 131, 132). The storage nodes 131, 132 may for example be arranged closer to the front side of the pixel 100 than to a backside of the pixel 100.

According to an example, the first and second storage nodes 131, 132 are memory nodes of the pixel 100. According to another example, the first and second storage nodes 131, 132 are pinned diodes of the pixel 100. The storage nodes 131, 132 may be arranged within one or more epitaxial layers of the pixel 100. The storage nodes 131, 132 may for example comprise an n-doped region of the pixel 100. The storage nodes 131, 132 may be surrounded by p-wells of the pixel 100.

The first field plate 141 is arranged next to the first storage node 131 at a first lateral side of the pixel 100 and the second field plate 142 is arranged next to the second storage node 132 at an opposite second lateral side of the pixel 100 (wherein the lateral sides of the pixel 100 are indicated by dashed lines in FIG. 1). The first and second field plates 141, 142 are configured to be supplied with a negative bias voltage such that the first and second field plates 141, 142 provide electrical isolation for the first, respectively the second storage node 131, 132. In this context “providing electrical isolation” for the storage nodes 131, 132 may mean that the field plates 141, 142 are configured to electrically isolate the storage nodes 131, 132 towards one or more other pixels arranged next to the pixel 100. In this way, no electrons or almost no electrons generated in the one or more neighboring pixels can diffuse into the storage nodes 131, 132 (such electrons would contribute to a dark current).

The field plates 141, 142 may be used instead of a junction isolation or instead of a shallow trench isolation (STI) for isolating the storage nodes 131, 132. Using the field plates 141, 142 instead of an STI, the pixel 100 may exhibit a reduced dark current because a comparatively large contribution to the dark current comes from recombinations at the STI interface. This contribution can be eliminated by employing the field plates 141, 142 instead. Furthermore, the field plates 141, 142 may have less of an impact on full well capacitance of the storage nodes 131, 132 compared to a junction isolation.

The field plates 141, 142 may for example comprise a first, respectively a second polysilicon structure. The polysilicon structure may be arranged at or over the front side of the pixel 100, for example in the same plane as the modulation gates 121, 122. In this case, the field plates 141, 142 may be fabricated in the same process as the modulation gates 121, 122.

According to another example, the field plates 141, 142 may comprise a first, respectively a second trench which may extend into one or more epitaxial layers and possibly also into a bulk semiconductor part of the pixel 100. The trenches may for example extend into the pixel 100 from the front side of the pixel 100. The trenches comprise an electrically conductive coating or an electrically conductive filling such that the bias voltage can be applied.

In general, the field plates 141, 142 may comprise any suitable structure and any suitable material configured to be supplied with the bias voltage such that the storage nodes 131, 132 can be electrically isolated as described above. In order to provide the bias voltage, the field plates 141, 142 may be electrically coupled to contacts of the pixel 100 (in particular, the first field plate 141 may be coupled to a first contact and the second field plate 142 may be coupled to a second contact). The contacts may for example comprise metal traces.

According to an example, these contacts are at least partially arranged within a dielectric layer, wherein the dielectric layer is arranged above the photoactive region 110, above the first and second modulation gates 121, 122 and above the first and second field plates 141, 142 (in other words, the contacts are arranged at the front side of the pixel 100). The dielectric layer may in particular cover the modulation gats 121, 122 and the field plates 141, 142. The dielectric layer may for example comprise an oxide, e.g., silicon oxide.

According to another example, the contacts are at least partially arranged within a semiconductor substrate of the pixel 100. In this case, the contacts may comprise vias.

The field plates 141, 142 may have any suitable shape and any suitable dimensions. The field plates 141, 142 may for example have a rectangular footprint as shown in FIG. 1. The footprint may for example have a length measured along a longer side of the footprint in the range of about 1 μm to about 10 μm. The lower limit of this range may also be about 2 μm, about 3 μm, about 4 μm, or about 5 μm. The upper limit of this range may also be about 9 μm, about 8 μm, about 7 μm, or about 6 μm. The footprint may for example have a width measured along a shorter side of the footprint in the range of about 100 nm to about 1 μm. The lower limit of this range may also be about 150 nm, about 200 nm, about 300 nm, about 400 nm, or about 500 nm. The upper limit of this range may also be about 900 nm, about 800 nm, about 700 nm, or about 600 nm.

According to an example, the pixel 100 may be part of an array of pixels, wherein the first field plate 141 is shared between the pixel 100 and a first adjacent pixel and/or wherein the second field plate 142 is shared between the pixel 100 and a second adjacent pixel. In other words, the first and second field plates 141, 142 are configured to provide electrical isolation for respective storage nodes of respective adjacent pixels.

In the example shown in FIG. 1 the pixel 100 comprises two storage nodes 131, 132 and two field plates 141, 142. However, the pixel 100 may comprise any suitable number of storage nodes and/or field plates, for example three storage nodes or four storage nodes and/or three field plates or four field plates. The further storage nodes and/or further field plates may for example be arranged at one or more of the remaining lateral sides of the pixel 100.

FIG. 2 shows an optical sensor 200 comprising a sensor part 210 and a control part 220 (e.g., a controller). The sensor part 210 comprises one or more pixels 100, in particular an array of pixels 100. The control part 220 is configured to control the sensor part 210.

For example, the control part 220 may be configured to control the modulation gates 121, 122 of the pixel 100. The control part 220 may also be configured to set a voltage value of the bias voltage for the field plates 141, 142. The control part 220 may in particular be configured to set the negative bias voltage to a first voltage value during a light detection state of the pixel 100 and to set the negative bias voltage to a second, higher voltage value (e.g., a more negative voltage value) during a readout state of the pixel. The second, higher voltage value may help with flushing the photo-electrons out of the storage nodes 131, 132 during read out of the pixel 100. This may speed up the readout process.

According to an example, the control part is configured to set identical voltage values for the bias voltage of the first field plate 141 and the second field plate 142. According to another example, the control part may set different voltage values for the bias voltage of the first field plate 141 on the one hand and the second field plate 142 on the other hand.

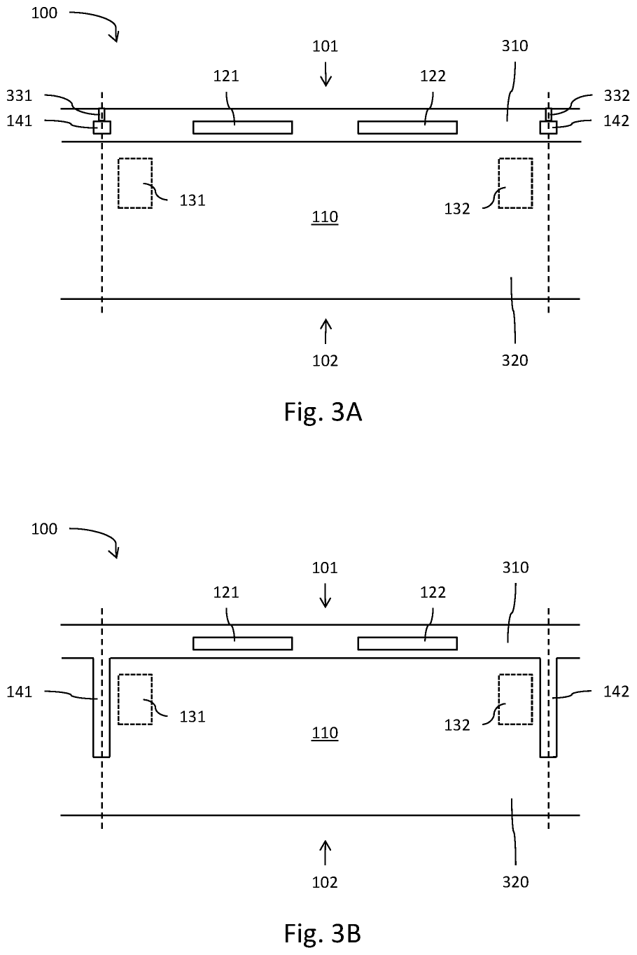

FIGS. 3A and 3B show sectional views of the pixel 100 according to two different specific examples.

In the example shown in FIG. 3A, the pixel 100 comprises first and second field plates 141, 142 which comprise or consist of a first and a second polysilicon structure. The field plates 141, 142 (in particular, the polysilicon structures) may for example be arranged in (or over) a dielectric layer 310 of the pixel 100. The field plates 141, 142 may be arranged above a semiconductor part 320 of the pixel 100. The semiconductor part 320 may comprise one or more epitaxial layers, wherein the one or more epitaxial layers comprise the photoactive region 110. The semiconductor part 320 may further comprise a bulk semiconductor part, wherein the one or more epitaxial layers are arranged over the bulk semiconductor part. The field plates 141, 142 may be separated from the epitaxial layer(s) by the dielectric layer 310 or by a part of the dielectric layer 310 (e.g., a lower layer of a layer stack). In other words, in this example the field plates 141, 142 do not extend into the epitaxial layers. In particular, the dielectric layer 310 is arranged between the field plates 141, 142 and the storage nodes 131, 132. The dielectric layer 310 may comprise a layer stack. The dielectric layer 310 may comprise or consist of an oxide layer.

As shown in FIG. 3A, the first field plate 141 may be coupled to a first contact 331 and the second field plate 142 may be coupled to a second contact 332. The first and second contacts 331, 332 may e.g., comprise or consist of metal traces extending at least partially through the dielectric layer 310.

In the example shown in FIG. 3B, the pixel 100 comprises first and second field plates 141, 142 which comprise or consist of a first trench and a second trench. The first and second trenches comprise an electrically conductive coating or the first and second trenches are filled with electrically conductive material such that the bias voltage can be applied. The trenches may be coupled to first and second contacts (not shown in FIG. 3B). The contacts may e.g., extend towards the front side 101 or towards the backside 102 of the pixel 100.

As shown in FIGS. 3A and 3B, the pixel 100 may comprise the front side 101 and the backside 102. The backside 102 may be a side of the bulk semiconductor part of the pixel 100.

A thickness of the pixel 100 measured between the front side 101 and the backside 102 may for example be in the range of 4 μm to 20 μm. The lower limit of this range may also be about 6 μm, or about 10 μm and the upper limit may also be about 16 μm, or about 12 μm. A width of the pixel 100 measured between opposite lateral sides (the lateral sides are indicated by vertical dashed lines in FIGS. 3A and 3B) may for example be in the range of 2 μm to 10 μm. The lower limit of the range may also be about 4 μm or about 6 μm and the upper limit may also be about 8 μm.

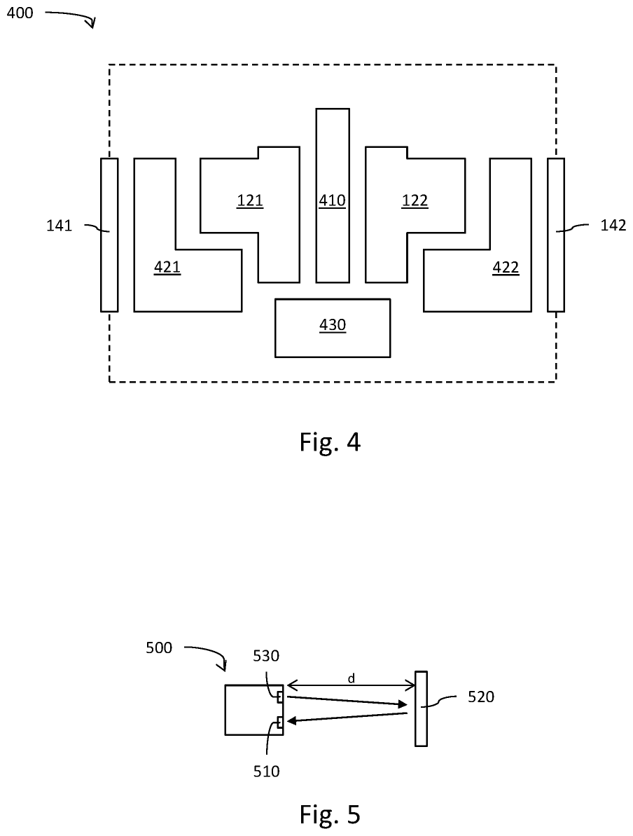

FIG. 4 shows a plan view of a further pixel 400 which may be similar or identical to the pixel 100. The pixel 400 may comprise all components described with respect to the pixel 100 and it may further comprise the components described in the following.

The pixel 400 may for example comprise further polysilicon structures. The pixel 400 may for example comprise a third modulation gate 410 which may be arranged between the first and second modulation gates 121, 122. Similar to the first and second modulation gates 121, 122, the third modulation gate 410 may be configured to enable indirect time of flight measurements with the pixel 400.

The pixel 400 may for example comprise a first transfer gate 421 and a second transfer gate 422. The first transfer gate 421 may be configured to transfer electrons accumulated in the first storage node 131 to a first readout part (not shown) at the end of the integration time interval for readout of the pixel 400. Similarly, the second transfer gate 422 may be configured to transfer electrons accumulated in the second storage node 132 to a second readout part (also not shown). Note that the storage nodes 131, 132 are not shown in FIG. 4.

According to an example, the pixel 400 may further comprise a drain 430. The drain 430 may for example be arranged laterally next to the modulation gates 121, 122 and 410.

FIG. 5 shows an example optical sensor unit 500 which may comprise a sensor part 510 and optionally an emitter part 530. The sensor part 510 may comprise the optical sensor 200 with one or more pixels 100 or 400, in particular an array of pixels 100 or 400. The optical sensor unit 500 may for example be a time of flight sensor unit configured to measure a distance d to an object 520 and/or to measure a speed of the object 520. The optional emitter part 530 is configured for emitting photons. According to another example, the sensor part 510 and the emitter part 530 are part of separate units.

According to an example, the optical sensor unit 500 (and consequently, the pixel 100 or the pixel 400) is configured for front side illumination. According to another example, the optical sensor unit 500 (and consequently, the pixel 100 or the pixel 400) is configured for backside illumination.

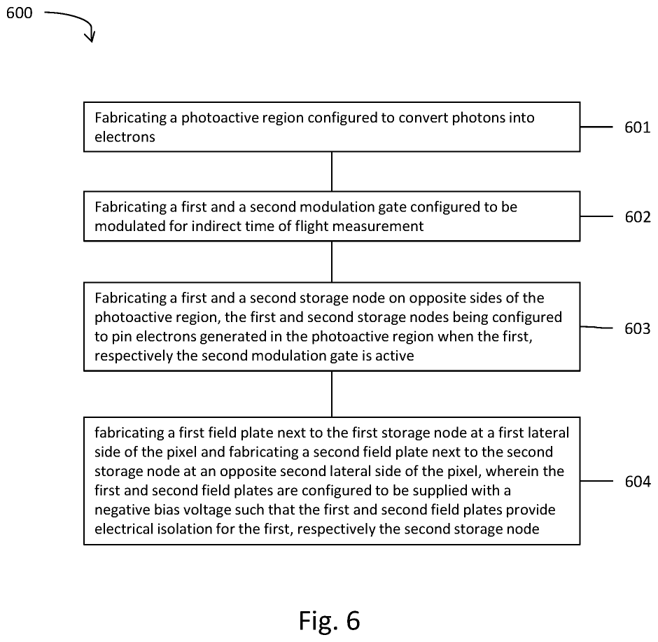

FIG. 6 is a flow chart of a method 600 for fabricating at least one pixel for an optical sensor. The method 600 may for example be used to fabricate the pixels 100 and 400.

The method 600 comprises at 601 a process of fabricating a photoactive region configured to convert photons into charge carriers, at 602 a process of fabricating a first and a second modulation gate configured to be modulated for indirect time of flight measurement, at 603 a process of fabricating a first and a second storage node on opposite sides of the photoactive region, the first and second storage nodes being configured to pin electrons generated in the photoactive region when the first, respectively the second modulation gate is active, and at 604 a process of fabricating a first field plate next to the first storage node at a first lateral side of the pixel and fabricating a second field plate next to the second storage node at an opposite second lateral side of the pixel, wherein the first and second field plates are configured to be supplied with a negative bias voltage such that the first and second field plates provide electrical isolation for the first, respectively the second storage node.

According to an example of the method 600, fabricating the first and second field plates comprises fabricating a first and a second polysilicon structure at a first side of the at least one pixel.

### Aspects

In the following, the optical sensor and the method for fabricating an optical sensor are further explained using specific aspects.
Aspect 1 is an optical sensor, including: at least one pixel, including: a photoactive region configured to convert photons into charge carriers, a first and a second modulation gate configured to be modulated for indirect time of flight measurement, a first and a second storage node arranged on opposite sides of the photoactive region, the first and second storage nodes being configured to pin electrons generated in the photoactive region when the first, respectively the second modulation gate is active, and a first field plate arranged next to the first storage node at a first lateral side of the pixel and a second field plate arranged next to the second storage node at an opposite second lateral side of the pixel, wherein the first and second field plates are configured to be supplied with a negative bias voltage such that the first and second field plates provide electrical isolation for the first, respectively the second storage node.
Aspect 2 is the optical sensor of aspect 1, wherein the first and second field plates include a first, respectively a second polysilicon structure.
Aspect 3 is the optical sensor of aspect 1, wherein the first and second field plates include a first, respectively a second trench including an electrically conductive coating.
Aspect 4 is the optical sensor of one of the preceding aspects, wherein the optical sensor includes an array of pixels, and wherein the field plates are configured to electrically isolate storage nodes of adjacent pixels of the array of pixels from one another.
Aspect 5 is the optical sensor of aspect 4, wherein adjacent pixels have shared field plates.
Aspect 6 is the optical sensor of one of the preceding aspects, further including: an oxide layer arranged between the field plates and the storage nodes.
Aspect 7 is the optical sensor of one of the preceding aspects, wherein the modulation gates and the field plates have the same material or material composition.
Aspect 8 is the optical sensor of one of the preceding aspects, wherein the negative bias voltage is a constant bias voltage.
Aspect 9 is the optical sensor of one of the preceding aspects, wherein the first and second field plates are coupled to first and second contacts, wherein the first and second contacts are at least partially arranged within a dielectric layer, the dielectric layer arranged above the photoactive region, above the first and second modulation gates and above the first and second field plates, and wherein the first and second contacts are configured to supply the first and second field plates with the negative bias voltage.
Aspect 10 is the optical sensor of one of aspect 9, wherein a control part of the optical sensor is configured to set the negative bias voltage to a first voltage value during a light detection state of the pixel and to set the negative bias voltage to a second, higher voltage value during a readout state of the pixel.
Aspect 11 is a method for fabricating at least one pixel for an optical sensor, the method including: fabricating a photoactive region configured to convert photons into charge carriers, fabricating a first and a second modulation gate configured to be modulated for indirect time of flight measurement, fabricating a first and a second storage node on opposite sides of the photoactive region, the first and second storage nodes being configured to pin electrons generated in the photoactive region when the first, respectively the second modulation gate is active, and fabricating a first field plate next to the first storage node at a first lateral side of the pixel and fabricating a second field plate next to the second storage node at an opposite second lateral side of the pixel, wherein the first and second field plates are configured to be supplied with a negative bias voltage such that the first and second field plates provide electrical isolation for the first, respectively the second storage node.
Aspect 12 is the method of aspect 11, wherein fabricating the first and second field plates includes fabricating a first and a second polysilicon structure at a first side of the at least one pixel.
Aspect 13 is the method of aspect 11 or 12, wherein the first and second field plates are fabricated in the same process as the first and second modulation gates.
Aspect 14 is the method of one of the aspects 11 to 13, further including: fabricating an oxide layer between the storage nodes and the field plates.
Aspect 15 is the method of one of the aspects 11 to 14, wherein the method includes fabricating an array of pixels for the optical sensor, and wherein the field plates are arranged at boundaries between adjacent pixels of the array of pixels.
Aspect 16 is an apparatus including means for performing the method according to anyone of aspects 11 to 15.
Aspect 17: An optical sensor, comprising: a pixel, comprising: a photoactive region configured to convert photons into charge carriers; a first second modulation gate and a second modulation gate configured to be modulated for indirect time of flight measurement; a first storage node and a second storage node arranged on opposite lateral sides of the photoactive region, the first storage node being configured to pin first electrons generated in the photoactive region when the first modulation gate is active, and the second storage node being configured to pin second electrons generated in the photoactive region when the second modulation gate is active; a first field plate arranged proximate to the first storage node at a first lateral side of the pixel, wherein the first field plate is configured to be supplied with a negative bias voltage such that the first field plate provides electrical isolation for the first storage node; and a second field plate arranged proximate to the second storage node at a second lateral side of the pixel that is opposite to the first lateral side, wherein the second field plate is configured to be supplied with the negative bias voltage such that the second field plate provides electrical isolation for the second storage node.
Aspect 18: The optical sensor of Aspect 1, wherein the first field plate comprise a first polysilicon structure and the second field plate comprises a second polysilicon structure.
Aspect 19: The optical sensor of any of Aspects 1-18, wherein the first field plate comprise a first trench comprising a first electrically conductive coating and the second field plate comprises a second trench comprising a second electrically conductive coating.
Aspect 20: The optical sensor of any of Aspects 1-19, wherein the optical sensor comprises an array of pixels, including the pixel, and wherein the first field plate is configured to electrically isolate the first storage node from a first adjacent pixel, and the second field plate is configured to electrically isolate the second storage node from a second adjacent pixel.
Aspect 21: The optical sensor of Aspect 20, wherein adjacent pixels of the array of pixels have shared field plates.
Aspect 22: The optical sensor of any of Aspects 1-21, further comprising: an oxide layer arranged between the first field plate and the first storage node, and between the second field plate and the second storage node.
Aspect 23: The optical sensor of any of Aspects 1-22, wherein the first and the second modulation gates and the first and the second field plates have a same material or a same material composition.
Aspect 24: The optical sensor of any of Aspects 1-23, wherein the negative bias voltage is a constant bias voltage.
Aspect 25: The optical sensor of any of Aspects 1-24, wherein the first field plate is coupled to a first contact, and the second field plate is coupled to a second contact, wherein the first and the second contacts are at least partially arranged within a dielectric layer, the dielectric layer arranged above the photoactive region, above the first and the second modulation gates, and above the first and the second field plates, and wherein the first and the second contacts are configured to supply the first and the second field plates with the negative bias voltage.
Aspect 26: The optical sensor of Aspect 25, further comprising: a controller configured to set the negative bias voltage to a first voltage value during a light detection state of the pixel and to set the negative bias voltage to a second voltage value during a readout state of the pixel, wherein the second voltage value is higher than the first voltage value.
Aspect 27: A method for fabricating a pixel of an optical sensor, the method comprising: fabricating a photoactive region configured to convert photons into charge carriers; fabricating a first modulation gate and a second modulation gate configured to be modulated for indirect time of flight measurement; fabricating a first storage node and a second storage node on opposite sides of the photoactive region, the first storage node being configured to pin first electrons generated in the photoactive region when the first modulation gate is active, and the second storage node being configured to pin second electrons generated in the photoactive region when the second modulation gate is active; fabricating a first field plate proximate to the first storage node at a first lateral side of the pixel, wherein the first field plate is configured to be supplied with a negative bias voltage such that the first field plate provides electrical isolation for the first storage node; and fabricating a second field plate proximate to the second storage node at a second lateral side of the pixel that is opposite to the first lateral side, wherein the second field plate is configured to be supplied with the negative bias voltage such that the second field plate provides electrical isolation for the second storage node.
Aspect 28: The method of Aspect 27, wherein fabricating the first field plate comprises fabricating a first polysilicon structure at the first lateral side, and wherein fabricating the second field plate comprises fabricating a second polysilicon structure at the second lateral side.
Aspect 29: The method of any of Aspects 27-28, wherein the first and the second field plates are fabricated in a same process as the first and the second modulation gates.
Aspect 30: The method of any of Aspects 27-29, further comprising: fabricating an oxide layer between the first field plate and the first storage node, and between the second field plate and the second storage node.
Aspect 31: The method of any of Aspects 27-30, wherein the method comprises: fabricating an array of pixels for the optical sensor, including the pixel, and wherein field plates are arranged at boundaries between adjacent pixels of the array of pixels.
Aspect 32: A system configured to perform one or more operations recited in one or more of Aspects 17-31.
Aspect 33: An apparatus comprising means for performing one or more operations recited in one or more of Aspects 17-31.

While the disclosure has been illustrated and described with respect to one or more implementations, alterations and/or modifications may be made to the illustrated aspects without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated example implementations of the disclosure.

1. An optical sensor, comprising:
a pixel, comprising:
a photoactive region configured to convert photons into charge carriers;
a first second modulation gate and a second modulation gate configured to be modulated for indirect time of flight measurement;
a first storage node and a second storage node arranged on opposite lateral sides of the photoactive region, the first storage node being configured to pin first electrons generated in the photoactive region when the first modulation gate is active, and the second storage node being configured to pin second electrons generated in the photoactive region when the second modulation gate is active;
a first field plate arranged proximate to the first storage node at a first lateral side of the pixel, wherein the first field plate is configured to be supplied with a negative bias voltage such that the first field plate provides electrical isolation for the first storage node; and
a second field plate arranged proximate to the second storage node at a second lateral side of the pixel that is opposite to the first lateral side, wherein the second field plate is configured to be supplied with the negative bias voltage such that the second field plate provides electrical isolation for the second storage node.

2. The optical sensor of claim 1, wherein the first field plate comprise a first polysilicon structure and the second field plate comprises a second polysilicon structure.

3. The optical sensor of claim 1, wherein the first field plate comprise a first trench comprising a first electrically conductive coating and the second field plate comprises a second trench comprising a second electrically conductive coating.

4. The optical sensor of claim 1, wherein the optical sensor comprises an array of pixels including the pixel, and
wherein the first field plate is configured to electrically isolate the first storage node from a first adjacent pixel, and the second field plate is configured to electrically isolate the second storage node from a second adjacent pixel.

5. The optical sensor of claim 4, wherein adjacent pixels of the array of pixels have shared field plates.

6. The optical sensor of claim 1, further comprising:
an oxide layer arranged between the first field plate and the first storage node, and between the second field plate and the second storage node.

7. The optical sensor of claim 1, wherein the first and the second modulation gates and the first and the second field plates have a same material or a same material composition.

8. The optical sensor of claim 1, wherein the negative bias voltage is a constant bias voltage.

9. The optical sensor of claim 1, wherein the first field plate is coupled to a first contact, and the second field plate is coupled to a second contact,
wherein the first and the second contacts are at least partially arranged within a dielectric layer, the dielectric layer arranged above the photoactive region, above the first and the second modulation gates, and above the first and the second field plates, and
wherein the first and the second contacts are configured to supply the first and the second field plates with the negative bias voltage.

10. The optical sensor of claim 9, further comprising:
a controller configured to set the negative bias voltage to a first voltage value during a light detection state of the pixel and to set the negative bias voltage to a second voltage value during a readout state of the pixel, wherein the second voltage value is higher than the first voltage value.

11. A method for fabricating a pixel of an optical sensor, the method comprising:
fabricating a photoactive region configured to convert photons into charge carriers;
fabricating a first modulation gate and a second modulation gate configured to be modulated for indirect time of flight measurement;
fabricating a first storage node and a second storage node on opposite sides of the photoactive region, the first storage node being configured to pin first electrons generated in the photoactive region when the first modulation gate is active, and the second storage node being configured to pin second electrons generated in the photoactive region when the second modulation gate is active;
fabricating a first field plate proximate to the first storage node at a first lateral side of the pixel, wherein the first field plate is configured to be supplied with a negative bias voltage such that the first field plate provides electrical isolation for the first storage node; and
fabricating a second field plate proximate to the second storage node at a second lateral side of the pixel that is opposite to the first lateral side, wherein the second field plate is configured to be supplied with the negative bias voltage such that the second field plate provides electrical isolation for the second storage node.

12. The method of claim 11, wherein fabricating the first field plate comprises fabricating a first polysilicon structure at the first lateral side, and
wherein fabricating the second field plate comprises fabricating a second polysilicon structure at the second lateral side.

13. The method of claim 11, wherein the first and the second field plates are fabricated in a same process as the first and the second modulation gates.

14. The method of claim 11, further comprising:
fabricating an oxide layer between the first field plate and the first storage node, and between the second field plate and the second storage node.

15. The method of claim 11, wherein the method comprises:
fabricating an array of pixels for the optical sensor, including the pixel, and
wherein field plates are arranged at boundaries between adjacent pixels of the array of pixels.
